(19) United States
(12) Patent Application Publication
(10) Pub. No.: US 2025/0311561 A1
(43) Pub. Date: Oct. 2, 2025

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: SAMTAE JEONG, Yongin-si (KR); JOONYONG PARK, Yongin-si (KR); YUNG BIN CHUNG, Yongin-si (KR); HYUNGSEOK KIM, Yongin-si (KR)

(21) Appl. No.: 19/025,082

(22) Filed: Jan. 16, 2025

(30) Foreign Application Priority Data
Apr. 2, 2024 (KR) 10-2024-0044606

(51) Int. Cl. H10K 59/124; H10K 59/123

(52) U.S. Cl. CPC H10K 59/124; H10K 59/123

(57) ABSTRACT

A display device includes an active pattern disposed on a substrate. A first insulating layer covers the active pattern. The first insulating layer includes a first hole defined therein. A first electrode is disposed on the first insulating layer. The first electrode includes a first bridge metal layer directly contacting the active pattern and a first upper metal layer disposed on the first bridge metal layer.

### CROSS-REFERENCE TO RELATED APPLICATION(S)

This application claims priority under 35 U.S.C. § 119 to Korean Patent Application No. 10-2024-0044606, filed on Apr. 2, 2024 in the Korean Intellectual Property Office, the disclosure of which is incorporated by reference in its entirety herein.

### 1. TECHNICAL FIELD

Embodiments of the present disclosure relate to a display device and an electronic device including the display device.

### 2. DISCUSSION OF RELATED ART

A display device is an electronic device that displays images to users for providing visual information. Among display devices, an organic light emitting diode display device has recently attracted attention.

The display device may include an active pattern and electrodes. The active pattern and the electrodes may be disposed on different layers from each other with an insulating layer therebetween. The active pattern may be in direct contact with some of the electrodes through a hole (e.g., a contact hole) formed in the insulating layer. Electrodes disposed on different layers may also be in direct contact with each other through a hole.

### SUMMARY

Embodiments of the present disclosure provide a display device with increased quality.

Embodiments of the present disclosure provide an electronic device including the display device.

According to an embodiment of the present disclosure, a display device includes an active pattern disposed on a substrate. A first insulating layer covers the active pattern. The first insulating layer includes a first hole defined therein. A first electrode is disposed on the first insulating layer. The first electrode includes a first bridge metal layer directly contacting the active pattern and a first upper metal layer disposed on the first bridge metal layer.

In an embodiment, the first bridge metal layer may be formed by atomic layer deposition (“ALD”).

In an embodiment, the first upper metal layer may be formed by physical vapor deposition (“PVD”) or chemical vapor deposition (“CVD”).

In an embodiment, the first insulating layer may include a first side surface area exposed by the first hole.

In an embodiment, the first bridge metal layer may cover an upper surface of the active pattern and the first side surface area of the first insulating layer.

In an embodiment, the first bridge metal layer may include at least one selected from a group consisting of indium (“In”), gallium (“Ga”), zinc (“Zn”), silicon (“Si”), and aluminum (“Al”).

In an embodiment, the first bridge metal layer may further include a noble metal. In an embodiment, a thickness of the first bridge metal layer may be less than or equal to about 500 angstroms.

In an embodiment, the display device may further include a second insulating layer disposed on the first insulating layer. The second insulating layer includes a second hole defined therein. The second hole overlaps the first hole in a plan view.

In an embodiment, the first electrode may be disposed on the second insulating layer.

In an embodiment, the second insulating layer may include a second side surface area exposed by the second hole.

In an embodiment, the first bridge metal layer may cover an upper surface of the active pattern and the second side surface area of the second insulating layer.

In an embodiment, the display device may further include a third insulating layer covering the first electrode. The third insulating layer includes a third hole defined therein. A second electrode is disposed on the third insulating layer and directly contacts the first electrode in the third hole.

In an embodiment, the second electrode may include, a second bridge metal layer directly contacting the first electrode and a second upper metal layer disposed on the second bridge metal layer.

In an embodiment, the second bridge metal layer may be formed by atomic layer deposition.

In an embodiment, the third insulating layer may include a third side surface area exposed by the third hole.

In an embodiment, the second bridge metal layer may cover an upper surface of the first electrode and the third side surface area of the third insulating layer.

In an embodiment, the second bridge metal layer may include at least one selected from a group consisting of indium, gallium, zinc, silicon, and aluminum.

In an embodiment, the second bridge metal layer may further include a noble metal.

According to an embodiment of the present disclosure, a display device includes a first electrode disposed on a substrate. An insulating layer covers the first electrode. The insulating layer includes a hole defined therein. A second electrode is disposed on the insulating layer. The second electrode includes a bridge metal layer directly contacting the first electrode and an upper metal layer disposed on the bridge metal layer.

In an embodiment, the bridge metal layer may be formed by atomic layer deposition.

In an embodiment, the insulating layer may include a side surface area exposed by the hole.

In an embodiment, the bridge metal layer may cover an upper surface of the first electrode and the side surface area of the insulating layer.

In an embodiment, the upper metal layer may be formed by physical vapor deposition or

chemical vapor deposition.

In an embodiment, a thickness of the bridge metal layer may be less than or equal to about 500 angstroms.

According to an embodiment of the present disclosure, an electronic device includes an active pattern disposed on a substrate. A first insulating layer covers the active pattern. The first insulating layer includes a first hole defined therein. A first electrode is disposed on the first insulating layer. The first electrode includes a first bridge metal layer directly contacting the active pattern and a first upper metal layer disposed on the first bridge metal layer. A memory device is configured to store data.

A display device according to an embodiment may include an active pattern disposed on a substrate, a first insulating layer covering the active pattern and having a first hole defined therein, and a first electrode disposed on the first insulating layer.

The first electrode includes a first bridge metal layer directly contacting the active pattern and a first upper metal layer disposed on the first bridge metal layer. The first bridge metal layer may be formed by atomic layer deposition (“ALD”). Accordingly, the first bridge metal layer having excellent step coverage may be applied to the first hole. Accordingly, a phenomenon in which the first electrode is disconnected may be prevented. In addition, the first upper metal layer may be formed by physical vapor deposition (“PVD”) or chemical vapor deposition (“CVD”). Accordingly, a deposition rate of the first electrode may be appropriately controlled.

### BRIEF DESCRIPTION OF THE DRAWINGS

Illustrative, non-limiting embodiments of the present disclosure will be more clearly understood from the following detailed description in conjunction with the accompanying drawings.

FIG. 1 is a plan view illustrating a display device according to an embodiment of the present disclosure.

FIG. 2 is a cross-sectional view of the display device of FIG. 1 taken along line I-II according to an embodiment of the present disclosure.

FIG. 3 is an enlarged cross-sectional view illustrating an example of area A of FIG. 2 according to an embodiment of the present disclosure.

FIG. 4 is an enlarged cross-sectional view illustrating another example of area A of FIG. 2 according to an embodiment of the present disclosure.

FIG. 5 is an enlarged cross-sectional view of area B of FIG. 2 according to an embodiment of the present disclosure.

FIGS. 6, 7, 8, and 9 are cross-sectional views illustrating a method of manufacturing the display device of FIG. 2 according to embodiments of the present disclosure.

FIG. 10 is a block diagram illustrating an electronic device according to embodiments.

FIG. 11 is a diagram illustrating an example in which the electronic device of FIG. 10 is implemented as a smart phone.

### DETAILED DESCRIPTION OF EMBODIMENTS

Hereinafter, display devices in accordance with non-limiting embodiments of the present disclosure will be described in more detail with reference to the accompanying drawings. The same reference numerals are used for the same components in the drawings, and redundant descriptions of the same components may be omitted.

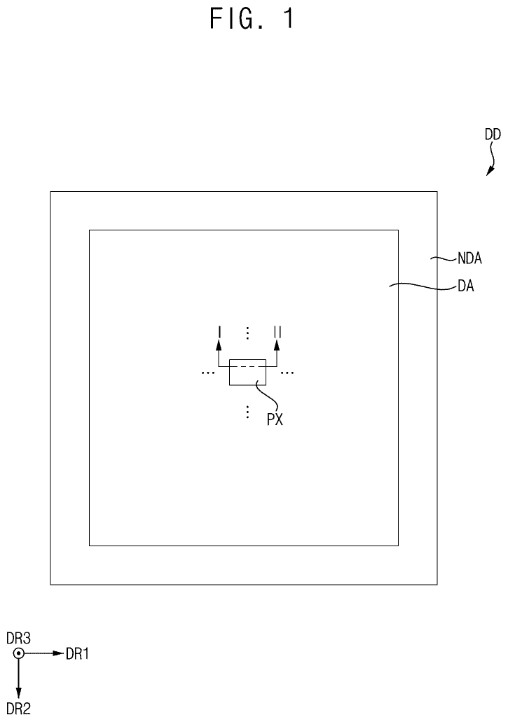

FIG. 1 is a plan view illustrating a display device according to an embodiment.

Referring to FIG. 1, a display device DD may include a display area DA and a non-display area NDA.

A plurality of pixels may be disposed in the display area DA. For example, a pixel PX may be disposed in the display area DA as shown in FIG. 1. Each of the plurality of pixels may emit light. For example, the pixel PX as shown in FIG. 1 may emit light.

In an embodiment, the plurality of pixels may be repeatedly arranged along a first direction DR1 and a second direction DR2 crossing the first direction DR1. Accordingly, an image may be displayed over the entire display area DA.

The non-display area NDA may be disposed around the display area DA. For example, the non-display area NDA may surround at least a portion of the display area DA in a plan view (e.g., in the first direction D1 and/or second direction D2). A driver may be disposed in the non-display area NDA. The driver may provide a signal or a voltage to the plurality of pixels. For example, in an embodiment the driver may include a data driver, a gate driver, and the like. The non-display area NDA may not display an image.

In an embodiment, the first direction DR1 and the second direction DR2 crossing the first direction DR1 may be defined. For example, in an embodiment the second direction DR2 may be perpendicular to the first direction DR1. However, embodiments of the present disclosure are not necessarily limited thereto, and the second direction DR2 may form an acute angle or an obtuse angle with the first direction DR1. In addition, a third direction DR3 crossing a plane formed by the first direction DR1 and the second direction DR2 may be defined. For example, in an embodiment the third direction DR3 may be perpendicular to the plane formed by the first direction DR1 and the second direction DR2 and may extend in a thickness direction of the display device DD. However, embodiments of the present disclosure are not necessarily limited thereto, and the third direction DR3 may form an acute angle or an obtuse angle with the plane formed by the first direction DR1 and the second direction DR2 in some embodiments.

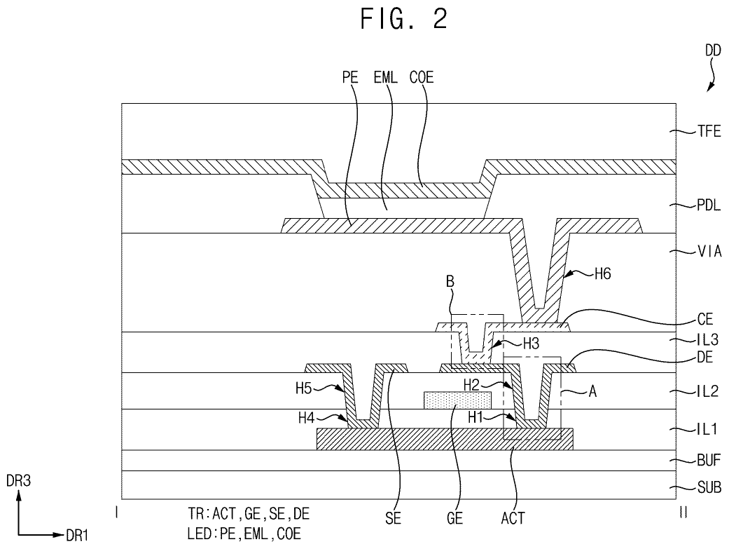

FIG. 2 is a cross-sectional view of the display device of FIG. 1 taken along line I-II.

Referring to FIG. 2, in an embodiment the display device DD may include a substrate SUB, a buffer layer BUF, a first insulating layer IL1, a second insulating layer IL2, a third insulating layer IL3, a transistor TR, a via insulating layer VIA, a pixel defining layer PDL, a light emitting element LED, a connection electrode CE, and an encapsulation layer TFE.

The substrate SUB may include a transparent material or an opaque material. For example, in an embodiment the substrate SUB may be formed of a transparent resin substrate. Example of the transparent resin substrate may include a polyimide substrate. In an embodiment, the polyimide substrate may include a first organic layer, a first barrier layer, a second organic layer, and the like.

Alternatively, in an embodiment the substrate SUB may include a quartz substrate (e.g. a synthetic quartz substrate, a fluorine-doped quartz substrate), a calcium fluoride substrate, a sodalime glass substrate, a non-alkali glass substrate, or the like. These materials may be used alone or in combination with each other.

The buffer layer BUF may be disposed on the substrate SUB (e.g., disposed directly thereon in the third direction DR3). The buffer layer BUF may prevent metal atoms or impurities from diffusing from the substrate SUB to the transistor TR. In addition, the buffer layer BUF can increase flatness of a surface of the substrate SUB when the surface of a substrate SUB is not uniform.

For example, in an embodiment the buffer layer BUF may include an inorganic material such as silicon oxide, silicon nitride, silicon carbide, silicon oxynitride, silicon oxycarbide. These materials may be used alone or in combination with each other.

In an embodiment, the transistor TR may include an active pattern ACT, a gate electrode GE, a source electrode SE, and a drain electrode DE.

The active layer ACT may be disposed on the buffer layer BUF (e.g., disposed directly thereon in the third direction DR3). In an embodiment, the active layer ACT may include an inorganic semiconductor (e.g., amorphous silicon, polysilicon, a metal oxide semiconductor,), an organic semiconductor, or the like. These materials may be used alone or in combination with each other. The active layer ACT may include a source area, a drain area, and a channel area disposed between the source area and the drain area.

In an embodiment, the metal oxide semiconductor may include a binary compound (“ABₓ”), a ternary compound (“ABₓC_{y}”), a quaternary compound (“ABₓC_{y}D_{z}”), or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like. These materials may be used alone or in combination with each other.

For example, in an embodiment the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The first insulating layer IL1 may be disposed on the buffer layer BUF (e.g., disposed directly thereon in the third direction DR3). The first insulating layer IL1 may cover the active pattern ACT. For example, the first insulating layer IL1 may cover the active pattern ACT and may be disposed along a profile of the active pattern ACT.

For example, in an embodiment the first insulating layer IL1 may include an inorganic material such as silicon oxide, silicon nitride, silicon carbide, silicon oxynitride, silicon oxycarbide. These materials may be used alone or in combination with each other.

The gate electrode GE may be disposed on the first insulating layer IL1 (e.g., disposed directly thereon in the third direction DR3). For example, the gate electrode GE may overlap the channel area of the active pattern ACT in a plan view.

In an embodiment, the gate electrode GE may include a metal, an alloy, a metal nitride, a conductive metal oxide, a transparent conductive material, or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other.

In an embodiment, examples of the conductive metal oxide may include indium tin oxide, indium zinc oxide, or the like. These materials may be used alone or in combination with each other. In addition, examples of the metal nitride may include aluminum nitride (“AlNₓ”), tungsten nitride (“WNₓ”), chromium nitride (“CrNₓ”), or the like. These materials may be used alone or in combination with each other.

In an embodiment, the second insulating layer IL2 may be disposed on the first insulating layer IL1 (e.g., disposed directly thereon in the third direction DR3). The second insulating layer IL2 may cover the gate electrode GE. For example, the second insulating layer IL2 may cover the gate electrode GE and may be disposed along a profile of the gate electrode GE.

For example, in an embodiment the second insulating layer IL2 may include an inorganic material such as silicon oxide, silicon nitride, silicon carbide, silicon oxynitride, silicon oxycarbide. These materials may be used alone or in combination with each other.

The first insulating layer IL1 may have a first hole H1 defined therein. For example, the first hole H1 may be formed in the first insulating layer IL1. The first hole H1 may at least partially overlap the active pattern ACT in the plan view. For example, in an embodiment the first hole H1 may be obtained by removing a portion of the first insulating layer IL1 from an upper surface of the first insulating layer IL1. For example, in an embodiment the first hole H1 may be obtained by removing a portion of the first insulating layer IL1 extending from the upper surface of the first insulating layer IL1 to an upper surface of the active pattern ACT.

The first insulating layer IL1 may have a fourth hole H4 defined therein. For example, the fourth hole H4 may be formed in the first insulating layer IL1. The fourth hole H4 may at least partially overlap the active pattern ACT in the plan view. The fourth hole H4 may be spaced apart from the first hole H1 in the plan view. For example, in an embodiment the fourth hole H4 may be spaced apart from the first hole H1 in a direction opposite to the first direction DR1. For example, the fourth hole H4 may obtained by removing a portion of the first insulating layer IL1 from the upper surface of the first insulating layer IL1. For example, the fourth hole H4 may be obtained by removing a portion of the first insulating layer IL1 extending from the upper surface of the first insulating layer IL1 to the upper surface of the active pattern ACT.

The second insulating layer IL2 may have a second hole H2 defined therein. For example, the second hole H2 may be formed in the second insulating layer IL2. For example, the second hole H2 may be obtained by removing a portion of the second insulating layer IL2 from an upper surface of the second insulating layer IL2. For example, in an embodiment the second hole H2 may be obtained by removing a portion of the second insulating layer IL2 extending from the upper surface of the second insulating layer IL2 to a lower surface of the second insulating layer IL2. The second hole H2 may overlap the first hole H1 in the plan view. For example, in an

embodiment the first hole H1 and the second hole H2 may be formed at the same time and may collectively form one hole.

The second insulating layer IL2 may have a fifth hole H5 defined therein. For example, the fifth hole H5 may be formed in the second insulating layer IL2. The fifth hole H5 may be spaced apart from the second hole H2 in the plan view. For example, in an embodiment the fifth hole H5 may be spaced apart from the second hole H2 in a direction opposite to the first direction DR1. For example, the fifth hole H5 may be obtained by removing a portion of the second insulating layer IL2 from the upper surface of the second insulating layer IL2. For example, in an embodiment the fifth hole H5 may be obtained by removing a portion of the second insulating layer IL2 extending from the upper surface of the second insulating layer IL2 to the lower surface of the second insulating layer IL2.

The fifth hole H5 may overlap the fourth hole H4 in the plan view. For example, in an embodiment the fourth hole H4 and the fifth hole H5 may be formed at the same time and may collectively form one hole.

The drain electrode DE may be disposed on the second insulating layer IL2 (e.g., disposed directly thereon in the third direction DR3). For example, the drain electrode DE may cover a portion of the upper surface of the second insulating layer IL2. In an embodiment, the drain electrode DE may be in direct contact with the active pattern ACT by extending through the first hole H1 and the second hole H2. For example, the drain electrode DE may be in direct contact with the drain area of the active pattern ACT by extending through the first hole H1 and the second hole H2. For example, the drain electrode DE may be referred to as a first electrode. However, embodiments of the present disclosure are not necessarily limited thereto and the first electrode may be various different electrodes.

The source electrode SE may be disposed on the second insulating layer IL2 (e.g., disposed directly thereon in the third direction DR3). The source electrode SE may be spaced apart from the drain electrode DE in the plan view. For example, in an embodiment the source electrode SE may be spaced apart from the drain electrode DE in a direction opposite to the first direction DR1. For example, the source electrode SE may cover a portion of the upper surface of the second insulating layer IL2. In an embodiment, the source electrode SE may be in direct contact with the active pattern ACT by extending through the fourth hole H4 and the fifth hole H5. For example, the source electrode SE may be in direct contact with the source area of the active pattern ACT through the fourth hole H4 and the fifth hole H5.

The third insulating layer IL3 may be disposed on the second insulating layer IL2 (e.g., disposed directly thereon in the third direction DR3). The third insulating layer IL3 may cover the source electrode SE and the drain electrode DE. For example, the third insulating layer IL3 may cover the source electrode SE and the drain electrode DE, and may be disposed along profiles of the source electrode SE and the drain electrode DE.

For example, in an embodiment the third insulating layer IL3 may include an inorganic material such as silicon oxide, silicon nitride, silicon carbide, silicon oxynitride, silicon oxycarbide. These materials may be used alone or in combination with each other.

The third insulating layer IL3 may have a third hole H3 defined therein. For example, the third hole H3 may be formed in the third insulating layer IL3. The third hole H3 may at least partially overlap the drain electrode DE in the plan view. For example, the third hole H3 may be obtained by removing a portion of the third insulating layer IL3 from an upper surface of the third insulating layer IL3. For example, the third hole H3 may be obtained by removing a portion of the third insulating layer IL3 extending from the upper surface of the third insulating layer IL3 to an upper surface of the drain electrode DE.

The connection electrode CE may be disposed on the third insulating layer IL3 (e.g., disposed directly thereon in the third direction DR3). For example, the connection electrode CE may cover a portion of the upper surface of the third insulating layer IL3. In an embodiment, the connection electrode CE may be in direct contact with the drain electrode DE by extending through the third hole H3. For example, the connection electrode CE may be referred to as a second electrode.

For example, in an embodiment the connection electrode CE may include a metal, an alloy, a metal nitride, a conductive metal oxide, a transparent conductive material, or the like.

In an embodiment, examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other.

In an embodiment, examples of the conductive metal oxide may include indium tin oxide, indium zinc oxide, or the like. These materials may be used alone or in combination with each other. In addition, examples of the metal nitride may include aluminum nitride (“AlNₓ”), tungsten nitride (“WNₓ”), chromium nitride (“CrNₓ”), or the like. These materials may be used alone or in combination with each other.

The via insulating layer VIA may be disposed on the third insulating layer IL3 (e.g., disposed directly thereon in the third direction DR3). The via insulating layer VIA may cover the connection electrode CE.

The via insulating layer VIA may include an organic material. For example, in an embodiment the via insulating layer VIA may include a phenolic resin, a polyacrylates resin, a polyimide resin, a polyamide resin, a siloxane resin, an epoxy resin, or the like. These materials may be used alone or in combination with each other.

In an embodiment, the via insulating layer VIA may have a sixth hole H6 defined therein. For example, the sixth hole H6 may be formed in the via insulating layer VIA. The sixth hole H6 may at least partially overlap the connection electrode CE in the plan view. For example, the sixth hole H6 may be obtained by removing a portion of the via insulating layer VIA from an upper surface of the via insulating layer VIA. For example, in an embodiment the sixth hole H6 may be obtained by removing a portion of the via insulating layer VIA from the upper surface of the via insulating layer VIA to an upper surface of the connection electrode CE.

In an embodiment, the light emitting element LED may include a pixel electrode PE, a light emitting layer EML, and a common electrode COE.

The pixel electrode PE may be disposed on the via insulating layer VIA (e.g., disposed directly thereon in the third direction DR3). For example, the pixel electrode PE may cover a portion of the upper surface of the via insulating layer VIA. In an embodiment, the pixel electrode PE may be in direct contact with the connection electrode CE by extending through the sixth hole H6.

For example, in an embodiment the pixel electrode PE may include a metal, an alloy, a metal nitride, a conductive metal oxide, a transparent conductive material, or the like. These materials may be used alone or in combination with each other. In an embodiment, the pixel electrode PE may have a stacked structure including ITO/Ag/ITO. For example, the pixel electrode PE may operate as an anode of the light emitting element LED.

The pixel defining layer PDL may be disposed on the via insulating layer VIA (e.g., disposed directly thereon in the third direction DR3). The pixel defining layer PDL may cover a side portion of the pixel electrode PE (e.g., lateral sides and lateral edges of the pixel electrode PE). For example, an opening exposing a portion of an upper surface of the pixel electrode PE may be defined in the pixel defining layer PDL.

For example, the pixel defining layer PDL may include an inorganic material or an organic material. In an embodiment, the pixel defining layer PDL may include an organic material such as an epoxy resin or a siloxane resin. These materials may be used alone or in combination with each other.

In an embodiment, the pixel defining layer PDL may further include a light-blocking material including a black pigment, a black dye, or the like.

The light emitting layer EML may be disposed on the pixel electrode PE (e.g., in the third direction DR3). In an embodiment, the light emitting layer EML may include an organic material that emits light of a preset color. For example, the light emitting layer EML may include an organic material that emits red light. However, embodiments of the present disclosure are not necessarily limited thereto.

The common electrode COE may be disposed on the light emitting layer EML and the pixel defining layer PDL (e.g., in the third direction DR3). In an embodiment, the common electrode COE may include a metal, an alloy, a metal nitride, a conductive metal oxide, a transparent conductive material, or the like. These materials may be used alone or in combination with each other. The common electrode COE may operate as a cathode of the light emitting element LED.

The encapsulation layer TFE may be disposed on the common electrode COE (e.g., disposed directly thereon in the third direction DR3). The encapsulation layer TFE may prevent impurities, moisture, and the like from penetrating into the light emitting element LED from an outside (e.g., the external environment). The encapsulation layer TFE may include at least one inorganic layer and at least one organic layer.

For example, in an embodiment the inorganic layer may include silicon oxide, silicon nitride, silicon oxynitride, or the like. These materials may be used alone or in combination with each other. The organic layer may include a cured polymer such as polyacrylate.

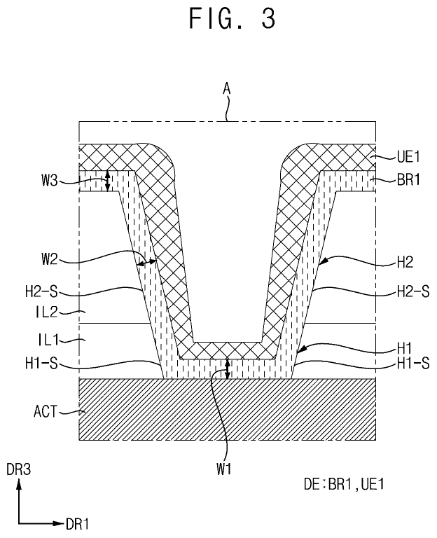

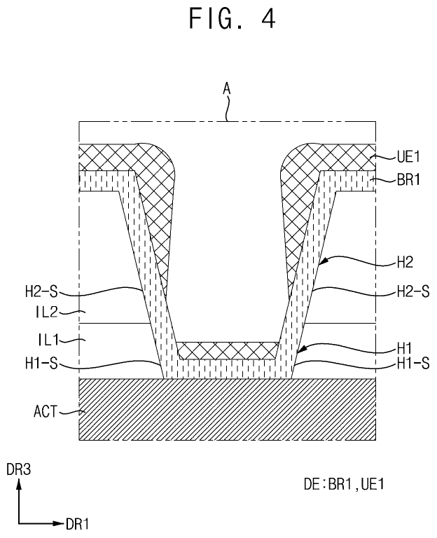

FIG. 3 is an enlarged cross-sectional view illustrating an example of area A of FIG. 2. FIG. 4 is an enlarged cross-sectional view illustrating another example of area A of FIG. 2.

Referring to FIG. 3, the drain electrode DE may be in direct contact with the active pattern ACT. For example, in an embodiment the drain electrode DE may be in direct contact with the active pattern ACT in the first hole H1. For example, the drain electrode DE may be in direct contact with the drain area of the active pattern ACT in the first hole H1.

The first insulating layer IL1 may include a first side surface area H1-S. The first side surface area H1-S may be a portion exposed by the first hole H1 (e.g., opposing lateral ends defining the first hole H1). For example, a portion of the first insulating layer IL1 may be removed to form the first hole H1, and the first hole H1 may be defined as a portion surrounded by the first side surface area H1-S. For example, the first insulating layer IL1 may include a first portion where the first hole H1 is formed and a second portion where the first hole H1 is not formed, and the first side surface area H1-S may be a boundary surface between the first portion and the second portion.

The second insulating layer IL2 may include a second side surface area H2-S. The second side surface area H2-S may be a portion exposed by the second hole H2 (e.g., opposing lateral ends defining the second hole H2). For example, a portion of the second insulating layer IL2 may be removed to form the second hole H2, and the second hole H2 may be defined as a portion surrounded by the second side surface area H2-S. For example, the second insulating layer IL2 may include a first portion where the second hole H2 is formed and a second portion where the second hole H2 is not formed, and the second side surface area H2-S may be a boundary surface between the first portion and the second portion.

In an embodiment, the drain electrode DE may include a first bridge metal layer BR1 and a first upper metal layer UE1. The first bridge metal layer BR1 may be in direct contact with the active pattern ACT. For example, the first bridge metal layer BR1 may cover the upper surface of the active pattern ACT. For example, a lowermost surface of the first bridge metal layer BR1 may directly contact and cover a portion of the upper surface of the active pattern ACT. In addition, the first bridge metal layer BR1 may directly contact and cover the first side area H1-S. In addition, the first bridge metal layer BR1 may directly contact and cover the second side area H2-S. In addition, the first bridge metal layer BR1 may directly contact and cover the upper surface of the first insulating layer IL1.

Referring further to FIG. 4, in an embodiment, the first bridge metal layer BR1 may be formed by atomic layer deposition (“ALD”). For example, an ALD process may be performed to form the first bridge metal layer BR1. Accordingly, the first bridge metal layer BR1 may have excellent step coverage. For example, the first bridge metal layer BR1 may have better step coverage than when formed by physical vapor deposition (“PVD”) or chemical vapor deposition (“CVD”).

Therefore, the first bridge metal layer BR1 may not be disconnected. For example, the first bridge metal layer BR1 may extend continuously and not be disconnected in the first hole H1. In an embodiment, the first upper metal layer UE1 may be formed by performing a physical vapor deposition process or a chemical vapor deposition process. Therefore, even if the first upper metal layer UE1 is disconnected in the first hole H1, as illustrated in FIG. 4 in which a lower portion of the first upper metal layer UE1 is disconnected, the drain electrode DE may not be disconnected from an overall viewpoint. For example, the drain electrode DE may remain electrically connected to the drain area of the active pattern ACT and a connection electrode CE, even if the first upper metal layer UE1, which may be formed by physical vapor deposition or chemical vapor deposition method, is disconnected in the first hole H1 due to the first bridge metal layer BR1 extending continuously and not being disconnected.

Referring back to FIG. 3, in an embodiment a thickness of the first bridge metal layer BR1 may be substantially constant. For example, a thickness W1 of the first bridge metal layer BR1 in direct contact with the upper surface of the active pattern ACT, a thickness W2 of the first bridge metal layer BR1 in direct contact with the first side area H1-S or a second side area H2-S, and a thickness W3 of the first bridge metal layer BR1 in direct contact with the upper surface of the first insulating layer IL1 may be substantially the same as each other.

In an embodiment, the thickness of the first bridge metal layer BR1 may be less than or equal to about 500 angstroms. For example, the thickness W1 of the first bridge metal layer BR1 in direct contact with the upper surface of the active pattern ACT, the thickness W2 of the first bridge metal layer BR1 in direct contact with the first side area H1-S or the second side area H2-S, and the thickness W3 of the first bridge metal layer BR1 in direct contact with the upper surface of the first insulating layer IL1 may be less than or equal to about 500 angstroms.

In an embodiment, a deposition rate of the first bridge metal layer BR1 may be relatively slow in an embodiment in which the first bridge metal layer BR1 is formed by atomic layer deposition. For example, the deposition rate of the first bridge metal layer BR1 may be slower than a deposition rate of the first bridge metal layer BR1 in an embodiment in which the first bridge metal layer BR1 is formed using physical vapor deposition or chemical vapor deposition. Therefore, in an embodiment in which the thickness of the first bridge metal layer BR1 exceeds about 500 angstroms, it may take a relatively long time for the first bridge metal layer BR1 to be formed.

For example, in an embodiment the first bridge metal layer BR1 may include indium (“In”), gallium (“Ga”), zinc (“Zn”), silicon (“Si”), aluminum (“Al”), or the like. These materials may be used alone or in combination with each other. In an embodiment, the first bridge metal layer BR1 may further include a noble metal. For example, in an embodiment the first bridge metal layer BR1 may further include ruthenium (“Ru”), rhodium (“Rh”), palladium (“Pd”), silver (“Ag”), osmium (“Os”), iridium (“Ir”), platinum (“Pt”), gold (“Au”), or the like. These materials may be used alone or in combination with each other. Alternatively, the first bridge metal layer BR1 may include only the noble metal. As the first bridge metal layer BR1 includes the noble metal, corrosion or oxidation of the first bridge metal layer BR1 may be suppressed.

The first upper metal layer UE1 may be disposed on the first bridge metal layer BR1 (e.g., disposed directly thereon). For example, the first upper metal layer UE1 may directly contact and cover the first bridge metal layer BR1. For example, the first upper metal layer UE1 may directly contact and cover an upper surface of the first bridge metal layer BR1.

In an embodiment, the first upper metal layer UE1 may be formed by physical vapor deposition or chemical vapor deposition. For example, a physical vapor deposition process or a chemical vapor deposition process may be performed to form the first upper metal layer UE1. For example, the first upper metal layer UE1 may be formed by physical vapor deposition. For example, the first upper metal layer UE1 may be formed by a sputtering process. However, embodiments of the present disclosure are not necessarily limited thereto.

In an embodiment, a deposition rate of the first upper metal layer UE1, which may be formed by physical vapor deposition or chemical vapor deposition, may be faster than the deposition rate of the first bridge metal layer BR1, which may be formed by atomic layer deposition. As the first upper metal layer UE1 is formed by physical vapor deposition or chemical vapor deposition, a deposition rate of the drain electrode DE may be appropriately controlled. For example, since the first upper metal layer UE1 is formed at a relatively high deposition rate, it may not take a long period of time for the drain electrode DE to be formed.

For example, since the drain electrode DE includes the first bridge metal layer BR1 and the first upper metal layer UE1, the drain electrode DE may not be disconnected in the first hole H1, and it may not take a long period of time for the drain electrode DE to be formed.

However, embodiments of the present disclosure are not necessarily limited thereto. For example, in an embodiment, the first upper metal layer UE1 may be formed by atomic layer deposition. For example, the first bridge metal layer BR1 and the first upper metal layer UE1 may be simultaneously formed by atomic layer deposition.

In an embodiment, the first upper metal layer UE1 may include a metal, an alloy, a metal nitride, a conductive metal oxide, a transparent conductive material, or the like. In an embodiment, examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other.

In an embodiment, examples of the conductive metal oxide may include indium tin oxide, indium zinc oxide, or the like. These materials may be used alone or in combination with each other. In addition, in an embodiment, examples of the metal nitride may include aluminum nitride (“AlNₓ”), tungsten nitride (“WNₓ”), chromium nitride (“CrNₓ”), or the like. These materials may be used alone or in combination with each other.

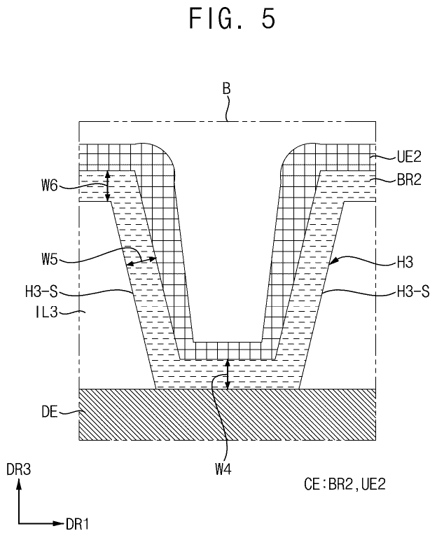

Although an example of the drain electrode DE has been described with reference to FIG. 3, embodiments of the present disclosure are not necessarily limited thereto, and any electrode connected to another electrode or an active pattern disposed below through a hole, such as the source electrode SE, the connection electrode CE, the pixel electrode PE of FIG. 2, may have substantially the same structure as the drain electrode DE. For example, the connection electrode CE may have substantially the same structure as the drain electrode DE. Hereinafter, a structure of the connection electrode CE will be described with reference to FIG. 5.

FIG. 5 is an enlarged cross-sectional view of area B of FIG. 2.

Referring to FIG. 5, the connection electrode CE may be in direct contact with the drain electrode DE. For example, in an embodiment a lower surface of the connection electrode CE may directly contact an upper surface of the drain electrode DE. For example, the connection electrode CE may be in direct contact with the drain electrode DE in the third hole H3.

The third insulating layer IL3 may include a third side surface area H3-S. The third side surface area H3-S may be a portion exposed by the third hole H3 (e.g., opposing lateral ends defining the third hole H3). For example, a portion of the third insulating layer IL3 may be removed to form the third hole H3, and the third hole H3 may be defined as a portion surrounded by the third side surface area H3-S. For example, the third insulating layer IL3 may include a first portion in which the third hole H3 is formed and a second portion in which the third hole H3 is not formed, and the third side surface area H3-S may be a boundary surface between the first portion and the second portion.

In an embodiment, the connection electrode CE may include a second bridge metal layer BR2 and a second upper metal layer UE2. The second bridge metal layer BR2 may be in direct contact with the drain electrode DE. For example, the second bridge metal layer BR2 may be in direct contact with the upper surface of the drain electrode DE. In addition, the second bridge metal layer BR2 may directly contact and cover the third side area H3-S. In addition, the second bridge metal layer BR2 may directly contact and cover the upper surface of the third insulating layer IL3.

In an embodiment, the second bridge metal layer BR2 may be formed by atomic layer deposition. Accordingly, the second bridge metal layer BR2 may have excellent step coverage. For example, the second bridge metal layer BR2 may have better step coverage than in an embodiment in which the second bridge metal layer BR2 is formed by physical vapor deposition or chemical vapor deposition.

Therefore, the second bridge metal layer BR2 may not be disconnected. For example, the second bridge metal layer BR2 may extend continuously and not be disconnected in the third hole H3. Therefore, even if the second upper metal layer UE2 is disconnected in the third hole H3, the connection electrode DE may not be disconnected from overall viewpoint and may maintain electrical connection, such as with the drain electrode DE. For example, even if the second upper metal layer UE2, which may be formed by physical vapor deposition or chemical vapor deposition method, is disconnected in the third hole H3, the second bridge metal layer BR2 extends continuously and is not disconnected. Accordingly the connection electrode CE may not be disconnected from the overall viewpoint and may maintain electrical connection, such as with the drain electrode DE.

In an embodiment, a thickness of the second bridge metal layer BR2 may be substantially constant. For example, in an embodiment a thickness W4 of the second bridge metal layer BR2 in direct contact with the upper surface of the drain electrode DE, a thickness W5 of the second bridge metal layer BR2 in direct contact with the third side area H3-S, and a thickness W6 of the second bridge metal layer BR2 in direct contact with the upper surface of the third insulating layer IL3 may be substantially the same as each other.

In an embodiment, the thickness of the second bridge metal layer BR2 may be less than or equal to about 500 angstroms. For example, the thickness W4 of the second bridge metal layer BR2 in direct contact with the upper surface of the drain electrode DE, the thickness W5 of the second bridge metal layer BR2 in direct contact with the third side area H3-S, and the thickness W6 of the second bridge metal layer BR2 in direct contact with the upper surface of the third insulating layer IL3 may be less than or equal to about 500 angstroms.

For example, in an embodiment the second bridge metal layer BR2 may include indium (“In”), gallium (“Ga”), zinc (“Zn”), silicon (“Si”), aluminum (“Al”), or the like. These materials may be used alone or in combination with each other. In an embodiment, the second bridge metal layer BR2 may further include a noble metal. For example, the first bridge metal layer BR1 may further include ruthenium (“Ru”), rhodium (“Rh”), palladium (“Pd”), silver (“Ag”), osmium (“Os”), iridium (“Ir”), platinum (“Pt”), gold (“Au”), or the like. These materials may be used alone or in combination with each other. Alternatively, the second bridge metal layer BR2 may include only the noble metal. Since the second bridge metal layer BR2 includes the noble metal, corrosion or oxidation of the second bridge metal layer BR2 may be suppressed.

The second upper metal layer UE2 may be disposed on the second bridge metal layer BR2 (e.g., disposed directly thereon). For example, the second upper metal layer UE2 may cover the second bridge metal layer BR2. For example, the second upper metal layer UE2 may cover an upper surface of the second bridge metal layer BR2.

In an embodiment, the second upper metal layer UE2 may be formed by physical vapor deposition or chemical vapor deposition. For example, the second upper metal layer UE2 may be formed by physical vapor deposition. For example, the second upper metal layer UE2 may be formed by a sputtering process. However, embodiments of the present disclosure are not necessarily limited thereto.

In an embodiment, a deposition rate of the second upper metal layer UE2 that is formed by physical vapor deposition or chemical vapor deposition may be faster than the deposition rate of the second bridge metal layer BR2 that is formed by atomic layer deposition. As the second upper metal layer UE2 is formed by physical vapor deposition or chemical vapor deposition, a deposition rate of the connection electrode CE may be appropriately controlled. For example, as the second upper metal layer UE2 is formed at a high deposition rate, it may not take a long time period for the connection electrode CE to be formed.

For example, as the connection electrode CE includes the second bridge metal layer BR2 and the second upper metal layer UE2, the connection electrode CE may not be disconnected in the third hole H3, and it may not take a long time period for the connection electrode CE to be formed.

However, embodiments of the present disclosure are not necessarily limited thereto. For example, in an embodiment, the second upper metal layer UE2 may be formed by atomic layer deposition. For example, the second bridge metal layer BR2 and the second upper metal layer UE3 may be simultaneously formed by atomic layer deposition.

In an embodiment, the second upper metal layer UE2 may include a metal, an alloy, a metal nitride, a conductive metal oxide, a transparent conductive material, or the like. In an embodiment, examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other.

In an embodiment, examples of the conductive metal oxide may include indium tin oxide, indium zinc oxide, or the like. These materials may be used alone or in combination with each other. In addition, in an embodiment, examples of the metal nitride may include aluminum nitride (“AlNₓ”), tungsten nitride (“WNₓ”), chromium nitride (“CrNₓ”), or the like. These materials may be used alone or in combination with each other.

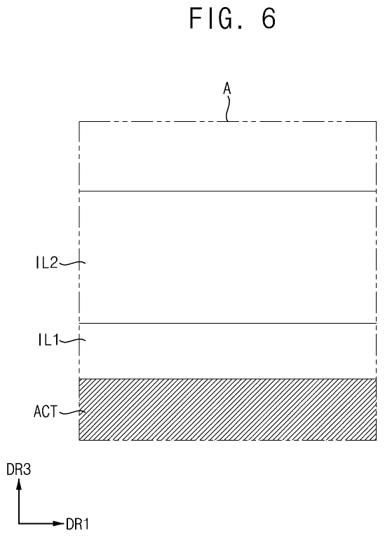

FIGS. 6, 7, 8, and 9 are cross-sectional views illustrating a method of manufacturing the display device of FIG. 2. Specifically, FIGS. 6, 7, 8, and 9 are cross-sectional views illustrating a method of manufacturing an area A of the display device of FIG. 2.

Referring to FIG. 6, the first insulating layer IL1 may be formed on the active pattern ACT (e.g., formed directly thereon in the third direction DR3). In addition, the second insulating layer IL2 may be formed on the first insulating layer IL1 (e.g., formed directly thereon in the third direction DR3).

The active layer ACT may be disposed on the buffer layer BUF (e.g., disposed directly thereon in the third direction DR3). In an embodiment, the active layer ACT may include an inorganic semiconductor (e.g., amorphous silicon, polysilicon, a metal oxide semiconductor, etc.), an organic semiconductor, or the like. These materials may be used alone or in combination with each other. The active layer ACT may include a source area, a drain area, and a channel area disposed between the source area and the drain area.

In an embodiment, the metal oxide semiconductor may include a binary compound (“ABₓ”), a ternary compound (“ABₓC_{y}”), a quaternary compound (“ABₓC_{y}D_{z}”), or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like. These materials may be used alone or in combination with each other.

For example, in an embodiment the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

In an embodiment, each of the first insulating layer IL1 and the second insulating layer IL2 may include an inorganic material such as silicon oxide, silicon nitride, silicon carbide, silicon oxynitride, silicon oxycarbide. These materials may be used alone or in combination with each other.

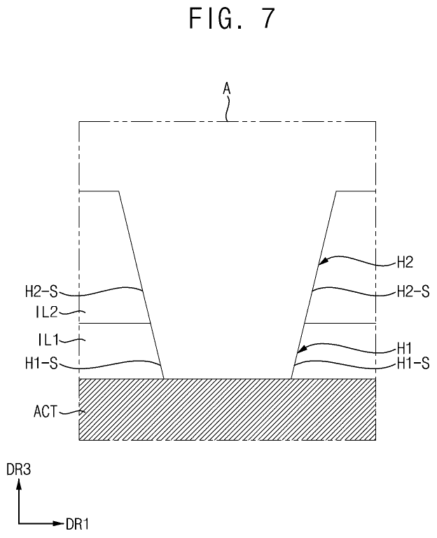

Referring to FIG. 7, the first hole H1 may be formed in the first insulating layer IL1. For example, the first hole H1 may be formed to at least partially overlap the active pattern ACT in the plan view. The second hole H2 may be formed in the second insulating layer IL2. The second hole H2 may be formed to overlap the first hole H1 in the plan view. For example, the first hole H1 and the second hole H2 may be formed simultaneously. For example, in an embodiment the first hole H1 and the second hole H2 may be formed simultaneously through a laser drilling method or the like.

As the first hole H1 is formed in the first insulating layer IL1, the first insulating layer IL1 may include the first side surface area H1-S(e.g., opposing lateral ends defining the first hole H1). As the second hole H2 is formed in the second insulating layer IL2, the second insulating layer IL2 may include the second side surface area H2-S(e.g., opposing lateral ends defining the second hole H2).

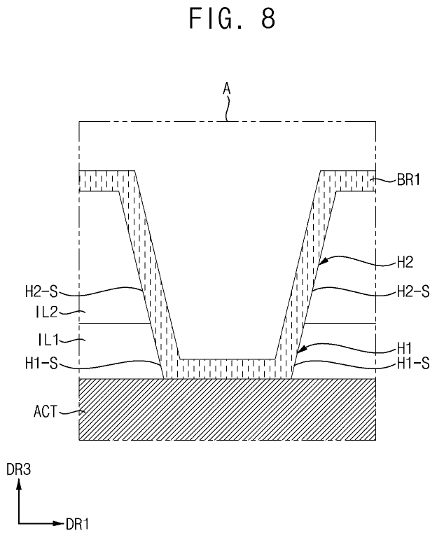

Referring to FIG. 8, the first bridge electrode BR1 may be formed on the second insulating layer IL2. For example, the first bridge electrode BR1 may be formed to directly contact and cover a portion of the upper surface of the second insulating layer IL2. The first bridge electrode BR1 may be formed in the first hole H1 and the second hole H2. For example, the first bridge electrode BR1 may be formed to directly contact and cover the upper surface, the second side area H2-S, and the first side area H1-S of the second insulating layer IL2. In an embodiment, the first bridge electrode BR1 may be formed in the first hole H1 to be direct in contact with the active pattern ACT. For example, in an embodiment a lower surface of the first bridge electrode BR1 may directly contact an upper surface of the active pattern ACT.

In an embodiment, the first bridge metal layer BR1 may be formed by atomic layer deposition. For example, the first bridge metal layer BR1 may include indium (“In”), gallium (“Ga”), zinc (“Zn”), silicon (“Si”), aluminum (“Al”), or the like. These materials may be used alone or in combination with each other. In an embodiment, the first bridge metal layer BR1 may further include a noble metal. For example, the first bridge metal layer BR1 may further include ruthenium (“Ru”), rhodium (“Rh”), palladium (“Pd”), silver (“Ag”), osmium (“Os”), iridium (“Ir”), platinum (“Pt”), gold (“Au”), or the like. These materials may be used alone or in combination with each other. Alternatively, the first bridge metal layer BR1 may include only the noble metal.

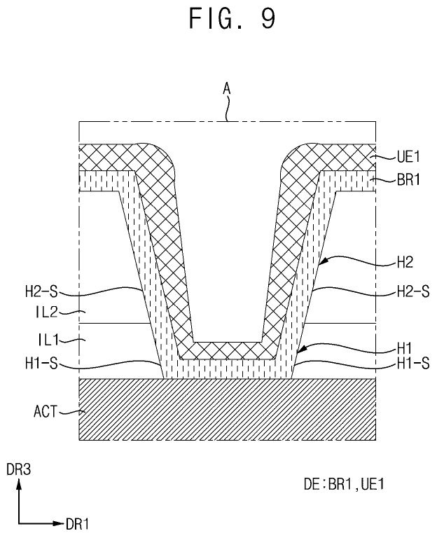

Referring to FIG. 9, the first upper metal layer UE1 may be formed on the first bridge metal layer BR1 (e.g., formed directly thereon). For example, the first upper metal layer UE1 may be formed to directly contact and cover the first bridge metal layer BR1. For example, the first upper metal layer UE1 may be formed to directly contact and cover the upper surface of the first bridge metal layer BR1.

In an embodiment, the first upper metal layer UE1 may be formed by physical vapor deposition or chemical vapor deposition. For example, the first upper metal layer UE1 may be formed by physical vapor deposition. For example, the first upper metal layer UE1 may be formed by a sputtering process. However, embodiments of the present disclosure are not necessarily limited thereto. For example, in an embodiment, the first upper metal layer UE1 may be formed by atomic layer deposition.

In an embodiment, the first upper metal layer UE1 may include a metal, an alloy, a metal nitride, a conductive metal oxide, a transparent conductive material, or the like. In an embodiment, examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other.

In an embodiment, examples of the conductive metal oxide may include indium tin oxide, indium zinc oxide, or the like. These materials may be used alone or in combination with each other. In addition, in an embodiment examples of the metal nitride may include aluminum nitride (“AlNₓ”), tungsten nitride (“WNₓ”), chromium nitride (“CrNₓ”), or the like. These materials may be used alone or in combination with each other.

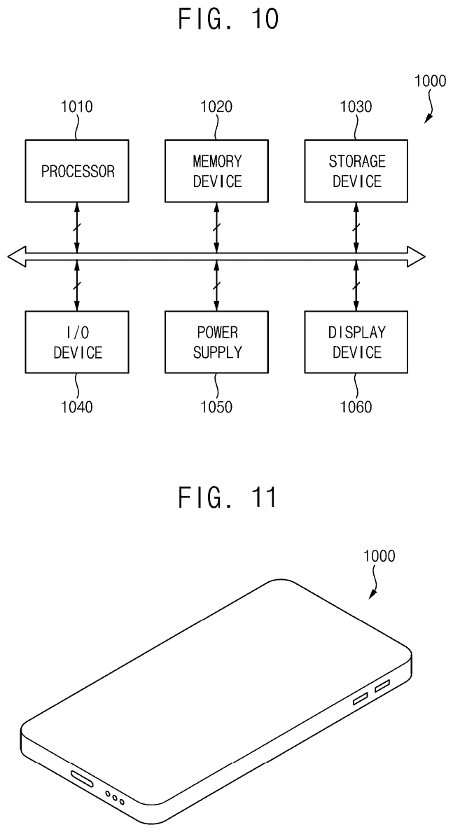

FIG. 10 is a block diagram illustrating an electronic device according to embodiments. FIG. 11 is a diagram illustrating an example in which the electronic device of FIG. 10 is implemented as a smart phone.

Referring to FIGS. 10 and 11, an electronic device 1000 may include a processor 1010, a memory device 1020, a storage device 1030, an input/output device 1040, a power supply 1050, and a display device 1060. In this case, the display device 1060 may be the display device DD of FIG. 1. In addition, the electronic device 1000 may further include several ports capable of communicating with a video card, a sound card, a memory card, a USB device, and/or the like.

According to an embodiment, as illustrated in the FIG. 11, the electronic device 1000 may be implemented as a smartphone. However, this is exemplary, and the electronic device 1000 may be implemented as various devices according to embodiments. For example, the electronic device 1000 may be implemented as a mobile phone, a video phone, a smart pad, a smart watch, a tablet PC, a vehicle navigation device, a computer monitor, a notebook computer, a head mounted display device, and/or the like.

The processor 1010 may be a microprocessor, a central processing unit, an application processor, and/or the like. The processor 1010 may be connected to other components through an address bus, a control bus, a data bus, and/or the like. In an embodiment, the processor 1010 may also be connected to an expansion bus such as a peripheral component interconnect (“PCI”) bus.

The memory device 1020 may store data necessary for operation of the electronic device 1000. For example, the memory device 1020 may include a nonvolatile memory device and/or a volatile memory device. Examples of the nonvolatile memory device may include erasable programmable read-only Memory (“EPROM”) device, electrically erasable programmable read-only memory (“EEPROM”) device, flash memory device, phase change random access memory (“PRAM”) device, resistance random access memory (“RRAM”) device, nano floating gate memory (“NFGM”) device, polymer random access memory (“PoRAM”) device, magnetic random access memory (“MRAM”) device, ferroelectric random access memory (“FRAM”) device, and/or the like. Example of the volatile memory device may include dynamic random access memory (“DRAM”) device, static random access memory (“SRAM”) device, mobile DRAM device, and/or the like.

The storage device 1030 may include a solid state drive (“SSD”), a hard disk drive (“HDD”), a CD-ROM, and/or the like.

The input/output device 1040 may include an input mean such as a keyboard, a keypad, a touch pad, a touch screen, and a mouse, and/or the like, and an output mean such as a speaker and a printer. In an embodiment, the display device 1060 may be included in the input/output device 1040.

The power supply 1050 may supply power necessary for operation of the electronic device 1000. For example, the power supply 1050 may supply power necessary for operation of the display device 1060.

The display device 1060 may be connected to other components through buses or other communication links.

Embodiments of the present disclosure can be applied to various display devices. For example, embodiments of the present disclosure may be applied to various display devices such as display devices for vehicles, ships and aircraft, portable communication devices, display devices for exhibition or information transmission, medical display devices, and the like. However, embodiments of the present disclosure are not necessarily limited thereto and the display devices may include various different small, medium and/or large sized electronic devices.

The foregoing is illustrative of embodiments and is not to be construed as limiting thereof. Although a few embodiments have been described, those skilled in the art will readily appreciate that many modifications are possible in the described embodiments without materially departing from the novel teachings and advantages of the present disclosure. Accordingly, all such modifications are intended to be included within the scope of embodiments of the present disclosure.

What is claimed is:

1. A display device comprising:
an active pattern disposed on a substrate;
a first insulating layer covering the active pattern, the first insulating layer including a first hole defined therein; and
a first electrode disposed on the first insulating layer, wherein the first electrode includes a first bridge metal layer directly contacting the active pattern and a first upper metal layer disposed on the first bridge metal layer.

2. The display device of claim 1, wherein the first bridge metal layer is formed by atomic layer deposition.

3. The display device of claim 2, wherein the first upper metal layer is formed by physical vapor deposition or chemical vapor deposition.

4. The display device of claim 3, wherein:
the first insulating layer includes a first side surface area exposed by the first hole; and
the first bridge metal layer covers an upper surface of the active pattern and the first side surface area of the first insulating layer.

5. The display device of claim 1, wherein the first bridge metal layer includes at least one selected from a group consisting of indium, gallium, zinc, silicon, and aluminum.

6. The display device of claim 5, wherein the first bridge metal layer further includes a noble metal.

7. The display device of claim 1, wherein a thickness of the first bridge metal layer is less than or equal to about 500 angstroms.

8. The display device of claim 1, further comprising:
a second insulating layer disposed on the first insulating layer, the second insulating layer including a second hole defined therein, the second hole overlapping the first hole in a plan view,
wherein the first electrode is disposed on the second insulating layer.

9. The display device of claim 8, wherein:
the second insulating layer includes a second side surface area exposed by the second hole; and
the first bridge metal layer covers an upper surface of the active pattern and the second side surface area of the second insulating layer.

10. The display device of claim 1, further comprising:
a third insulating layer covering the first electrode, the third insulating layer including a third hole defined therein; and
a second electrode disposed on the third insulating layer and directly contacting the first electrode in the third hole.

11. The display device of claim 10, wherein the second electrode includes;
a second bridge metal layer directly contacting the first electrode; and
a second upper metal layer disposed on the second bridge metal layer.

12. The display device of claim 11, wherein the second bridge metal layer is formed by atomic layer deposition.

13. The display device of claim 11, wherein:
the third insulating layer includes a third side surface area exposed by the third hole; and
the second bridge metal layer covers an upper surface of the first electrode and the third side surface area of the third insulating layer.

14. The display device of claim 13, wherein the second bridge metal layer includes at least one selected from a group consisting of indium, gallium, zinc, silicon, and aluminum.

15. The display device of claim 14, wherein the second bridge metal layer further includes a noble metal.

16. A display device comprising:
a first electrode disposed on a substrate;
an insulating layer covering the first electrode, the insulating layer including a hole defined therein; and
a second electrode disposed on the insulating layer, wherein the second electrode includes a bridge metal layer directly contacting the first electrode and an upper metal layer disposed on the bridge metal layer.

17. The display device of claim 16, wherein the bridge metal layer is formed by atomic layer deposition.

18. The display device of claim 17, wherein:
the insulating layer includes a side surface area exposed by the hole; and
the bridge metal layer covers an upper surface of the first electrode and the side surface area of the insulating layer.

19. The display device of claim 17, wherein the upper metal layer is formed by physical vapor deposition or chemical vapor deposition.

20. The display device of claim 17, wherein a thickness of the bridge metal layer is less than or equal to about 500 angstroms.

21. An electronic device comprising:
an active pattern disposed on a substrate;
a first insulating layer covering the active pattern, the first insulating layer including a first hole defined therein;
a first electrode disposed on the first insulating layer, wherein the first electrode includes a first bridge metal layer directly contacting the active pattern and a first upper metal layer disposed on the first bridge metal layer; and
a memory device configured to store data.
